(19) United States
(12) Patent Application Publication
(10) Pub. No.: US 2024/0363334 A1
(43) Pub. Date: Oct. 31, 2024

(54) METHOD OF PROCESSING SUBSTRATE, METHOD OF MANUFACTURING SEMICONDUCTOR DEVICE, RECORDING MEDIUM, AND SUBSTRATE PROCESSING APPARATUS

(71) Applicant: Kokusai Electric Corporation, Tokyo (JP)

(72) Inventors: Keitaro HAMADA, Toyama-shi (JP); Masaya NISHIDA, Toyama-shi (JP)

(73) Assignee: Kokusai Electric Corporation, Tokyo (JP)

(21) Appl. No.: 18/609,345

(22) Filed: Mar. 19, 2024

(30) Foreign Application Priority Data
Apr. 27, 2023 (JP) 2023-073800

(51) Int. Cl. H01L 21/02; C23C 16/34; C23C 16/455; C23C 16/52

(52) U.S. Cl. CPC H01L 21/02118; C23C 16/347; C23C 16/45527; C23C 16/45544; C23C 16/52; H01L 21/0228

(57) ABSTRACT

There is provided a technique that includes: (a) performing a cycle including supplying a source containing a predetermined element, carbon, and hydrogen to a substrate and supplying a first modifying agent containing nitrogen to the substrate, a predetermined number of times to form, on the substrate, a first film containing the predetermined element, nitrogen, carbon, and hydrogen bonded to carbon; and (b) supplying, to the substrate on which the first film is formed, a second modifying agent that is different from the first modifying agent and contains a compound containing a nitrogen-hydrogen bond and a nitrogen-nitrogen bond per molecule or a derivative of the compound, to modify the first film to a second film that is lower in content rate of the hydrogen bonded to carbon than the first film and contains the predetermined element, carbon, and nitrogen.

### CROSS-REFERENCE TO RELATED APPLICATIONS

This application is based upon and claims the benefit of priority from Japanese Patent Application No. 2023-073800, filed on Apr. 27, 2023, the entire contents of which are incorporated herein by reference.

### FIELD

The present disclosure relates to a method of processing a substrate, a method of manufacturing a semiconductor device, a recording medium, and a substrate processing apparatus.

### DESCRIPTION OF THE RELATED ART

In some cases, as a partial process in a process of manufacturing a semiconductor device, performed is the processing of supplying a plurality of types of processing gas to a substrate to form a carbonitride film on the substrate.

### SUMMARY

As described above, in forming a carbonitride film on a substrate, in some cases, for examples, impurities, such as hydrogen (H) bonded to carbon (C), remain in the carbonitride film, leading to influence on film properties.

Some embodiments of the present disclosure provide a technique enabling a film formed on a substrate to be improved in property.

According to an embodiment of the present disclosure, there is provided a technique that includes:
(a) performing a cycle including supplying a source containing a predetermined element, carbon, and hydrogen to a substrate and supplying a first modifying agent containing nitrogen to the substrate, a predetermined number of times to form, on the substrate, a first film containing the predetermined element, nitrogen, carbon, and hydrogen bonded to carbon; and
(b) supplying, to the substrate on which the first film is formed, a second modifying agent that is different from the first modifying agent and contains a compound containing a nitrogen-hydrogen bond and a nitrogen-nitrogen bond per molecule or a derivative of the compound, to modify the first film to a second film that is lower in content rate of the hydrogen bonded to carbon than the first film and contains the predetermined element, carbon, and nitrogen.

### BRIEF DESCRIPTION OF THE DRAWINGS

FIG. 1 illustrates a schematic configuration of an upright process furnace in a substrate processing apparatus favorably used in an embodiment of the present disclosure, with a longitudinal sectional view of a process furnace portion.

FIG. 2 illustrates a schematic configuration of the upright process furnace in the substrate processing apparatus favorably used in the embodiment of the present disclosure, with a sectional view of the process furnace portion taken along line A-A of FIG. 1.

FIG. 3 illustrates a schematic configuration of a controller in the substrate processing apparatus favorably used in the embodiment of the present disclosure, with a block diagram of a control system for the controller.

FIG. 4 is a flowchart of a substrate processing process favorably used in the embodiment of the present disclosure.

FIG. 5A is an explanatory view for a state on the surface of a substrate having a source adsorbing thereto in supplying a first modifying agent onto the substrate. FIG. 5B is an explanatory view for a state on the surface of a substrate having a source adsorbing thereto in supplying a second modifying agent onto the substrate.

FIG. 6 is a flowchart of a modified example of the substrate processing process favorably used in the embodiment of the present disclosure.

### DETAILED DESCRIPTION

### Embodiment of Present Disclosure

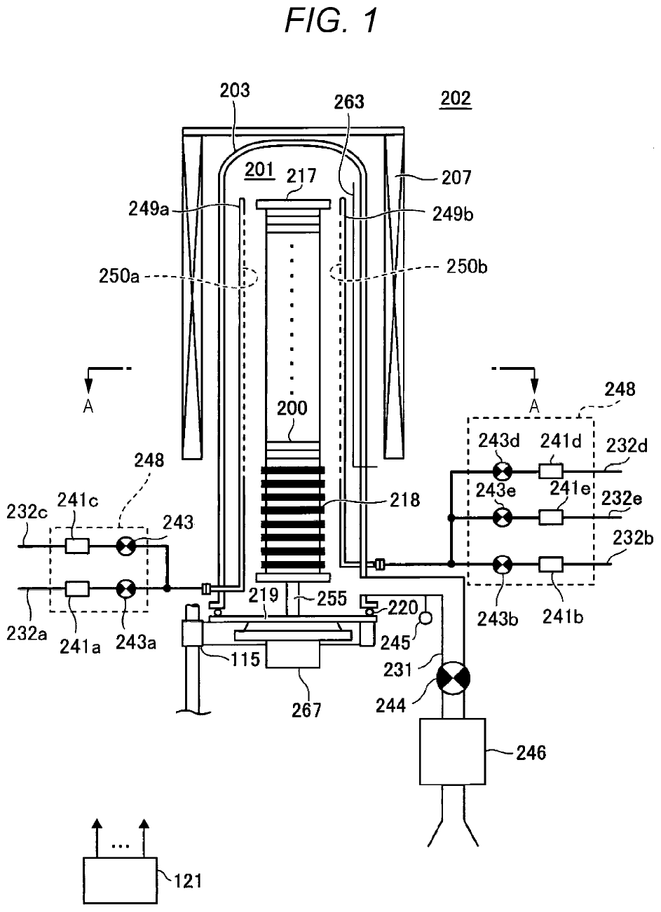

An embodiment of the present disclosure will be described below mainly with reference to FIGS. 1 to 5B. Note that the drawings used in the following description are all schematic and thus, for example, the dimensional relationship between each constituent element and the ratio between each constituent element in the drawings do not necessarily coincide with realities. In addition, for example, a plurality of drawings does not necessarily coincide with each other in the dimensional relationship between each constituent element or in the ratio between each constituent element.

### (1) Configuration of Substrate Processing Apparatus

As illustrated in FIG. 1, a process furnace 202 includes a heater 207 serving as a heater (temperature regulator). The heater 207 is cylindrical in shape and is vertically installed by being supported by a holding plate. The heater 207 further functions as an activator (exciter) that thermally activates (excites) gas.

Inside the heater 207, a reaction tube 203 is disposed concentrically with the heater 207. For example, the reaction tube 203 is made of a heat-resistant material, such as quartz (SiO₂) or silicon carbide (SiC), and is cylindrical in shape with an upper end occluded and a lower end open. The reaction tube 203 has a tubular hollow forming a process chamber 201. The process chamber 201 is capable of housing wafers 200 each serving as a substrate. Such wafers 200 are processed in the process chamber 201.

Nozzles 249a and 249b penetrating through the lower side wall of the reaction tube 203 are disposed in the process chamber 201. The nozzles 249a and 249b have, respectively, gas supply pipes 232a and 232b connected thereto.

The gas supply pipe 232a is provided with a mass flow controller (MFC) 241a serving as a flow rate controller and a valve 243a serving as an on/off valve in the order from the upstream side of a gas flow. The gas supply pipe 232b is provided with a mass flow controller (MFC) 241b serving as a flow rate controller and a valve 243b serving as an on/off valve in the order from the upstream side of a gas flow. A gas supply pipe 232c is connected to the downstream side of the valve 243a of the gas supply pipe 232a. Gas supply pipes 232d and 232e are each connected to the downstream side of the valve 243b of the gas supply pipe 232b. The gas supply pipe 232c is provided with a MFC 241c and a valve 243c in the order from the upstream side of a gas flow. The gas supply pipe 232d is provided with a MFC 241d and a valve 243d in the order from the upstream side of a gas flow. The gas supply pipe 232e is provided with a MFC 241e and a valve 243e in the order from the upstream side of a gas flow.

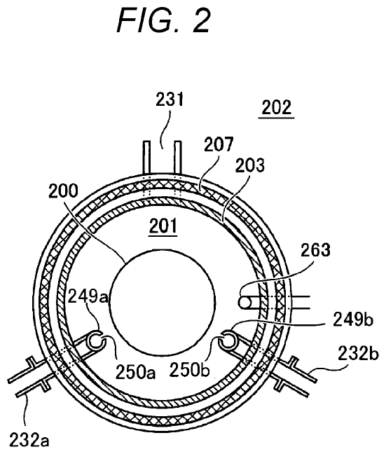

As illustrated in FIG. 2, the annular space in plan view between the inner wall of the reaction tube 203 and a wafer 200 is provided with the nozzles 249a and 249b each extending upward in the direction of an array of wafers 200 along the inner wall of the reaction tube 203 from the lower portion to upper portion of the inner wall. That is, the nozzles 249a and 249b are each provided, in a lateral region horizontally surrounding a wafer array region in which wafers 200 are arrayed, along the wafer array region. The nozzle 249a has a side face provided with a gas supply hole 250a for supplying gas. The nozzle 249b has a side face provided with a gas supply hole 250b for supplying gas. The gas supply holes 250a and 250b are each open toward the center of the reaction tube 203 and are each capable of supplying gas to the wafer 200. Such a plurality of gas supply holes 250a and a plurality of gas supply holes 250b are provided ranging from the lower portion to upper portion of the reaction tube 203.

Source gas that is a source containing a predetermined element, carbon (C), and hydrogen (H) is supplied from the gas supply pipe 232a into the process chamber 201 through the MFC 241a, the valve 243a, and the nozzle 249a.

In the present specification, the source gas corresponds to a source in a gaseous state, such as gas obtained by vaporizing a source in a liquid state under normal temperature and normal pressure or a source in a gaseous state under normal temperature and normal pressure. The term “source” in the present specification means a “liquid source in a liquid state”, “source gas in a gaseous state, or both thereof.

A first modifying agent containing nitrogen (N) is supplied from the gas supply pipe 232b into the process chamber 201 through the MFC 241b, the valve 243b, and the nozzle 249b. The first modifying agent can be referred to as a first modifying gas or a first nitriding agent.

The term “agent” in the present specification means an agent containing at least either a gaseous substance or a liquid substance. Examples of such a liquid substance include a mist substance. That is, a film-forming agent, a modifying agent, and an etching agent may each contain a gaseous substance, a liquid substance, such as a mist substance, or both thereof.

Inert gas is supplied from the gas supply pipe 232c into the process chamber 201 through the MFC 241c, the valve 243c, the gas supply pipe 232a, and the nozzle 249a. Inert gas is supplied from the gas supply pipe 232d into the process chamber 201 through the MFC 241d, the valve 243d, the gas supply pipe 232b, and the nozzle 249b. Such inert gas acts as purge gas, carrier gas, or diluent gas.

A second modifying agent that is different in type from the first modifying agent and is higher in reactivity than the first modifying agent is supplied from the gas supply pipe 232e into the process chamber 201 through the MFC 241e, the valve 243e, the gas supply pipe 232b, and the nozzle 249b. The second modifying agent can be referred to as a second modifying gas or a second nitriding agent.

Mainly, the gas supply pipe 232a, the MFC 241a, and the valve 243a serve as a source gas supplier (source supplier) that supplies the source gas. Mainly, the gas supply pipe 232b, the MFC 241b, and the valve 243b serve as a first modifying agent supplier (first modifying gas supplier or first nitriding agent supplier) that supplies the first modifying agent. Mainly, the gas supply pipe 232c, the MFC 241c, and the valve 243c serve as an inert gas supplier that supplies the inert gas, and the gas supply pipe 232d, the MFC 241d, and the valve 243d serve as an inert gas supplier that supplies the inert gas. Mainly, the gas supply pipe 232e, the MFC 241e, and the valve 243e serve as a second modifying agent supplier (second modifying gas supplier or second nitriding agent supplier) that supplies the second modifying agent.

Any or all of the various types of suppliers described above may be achieved with an integrated supply system 248 including the valves 243a to 243e and the MFCs 241a to 241e integrated together. The integrated supply system 248 is connected to the gas supply pipes 232a to 232e such that a controller 121, described later, controls the operation of supplying various types of gas into the gas supply pipes 232a to 232e, namely, the operations of the valves 243a to 243e that open/shut and the operations of the MFCs 241a to 241e for regulation in flow rate. The integrated supply system 248 is provided as a single integrated unit or a splittable integrated unit and can be attached to/detached from the gas supply pipes 232a to 232e on an integrated unit basis. Thus, maintenance, replacement, or addition can be performed to the integrated supply system 248 on an integrated unit basis.

The side wall of the reaction tube 203 has a lower portion in connection with an exhaust pipe 231 that exhausts the atmosphere in the process chamber 201. A vacuum pump 246 serving as a vacuum exhaust is connected to the exhaust pipe 231 through a pressure sensor 245 serving as a pressure detector that detects the pressure in the process chamber 201 and an auto pressure controller (APC) valve 244 serving as a pressure regulator. With the vacuum pump 246 in operation, the APC valve 244 opens/shuts its valve to vacuum-exhaust the process chamber 201/stop the vacuum exhaust. Furthermore, with the vacuum pump 246 in operation, the APC valve 244 regulates the degree of valve opening based on pressure information detected by the pressure sensor 245 to regulate the pressure in the process chamber 201. Mainly, the exhaust pipe 231, the pressure sensor 245, and the APC valve 244 serve as an exhauster. The exhauster may include the vacuum pump 246.

A seal cap 219 serving as a furnace lid capable of airtightly occluding the opening at the lower end of the reaction tube 203 is provided below the reaction tube 203. The seal cap 219 is made of a metallic material, such as SUS, and is discoid in shape. The seal cap 219 has an upper face provided with an O-ring 220 serving as a seal member to have contact with the lower end of the reaction tube 203. A rotator 267 that rotates a boat 217, described later, is installed below the seal cap 219. The rotator 267 has a rotary shaft 255 that penetrates through the seal cap 219 and is connected to the boat 217. The rotator 267 rotates the boat 217 to rotate wafers 200. A boat elevator 115 serving as a lifter installed outside the reaction tube 203 raises/lowers the seal cap 219, vertically. The boat elevator 115 serves as a conveyor that raises/lowers the seal cap 219 to load/unload (convey) wafers 200 into/from the process chamber 201.

The boat 217 serving as a substrate support supports a plurality of wafers 200, for example, 25 to 200 wafers 200 such that the wafers 200, of which the postures are kept horizontal and the centers are aligned, are arrayed vertically on a multiple-stage basis, namely, at intervals. The boat 217 is made of a heat-resistant material, such as quartz or SiC. The boat 217 has a lower portion that supports heat insulating plates 218 made of a heat-resistant material, such as quartz or Sic, on a multiple-stage basis such that the postures of the heat insulating plates 218 are kept horizontal.

A temperature sensor 263 serving as a temperature detector is installed in the reaction tube 203. The degree of energization to the heater 207 is regulated based on temperature information detected by the temperature sensor 263, so that a desired temperature distribution is obtained in the process chamber 201. The temperature sensor 263 is provided along the inner wall of the reaction tube 203.

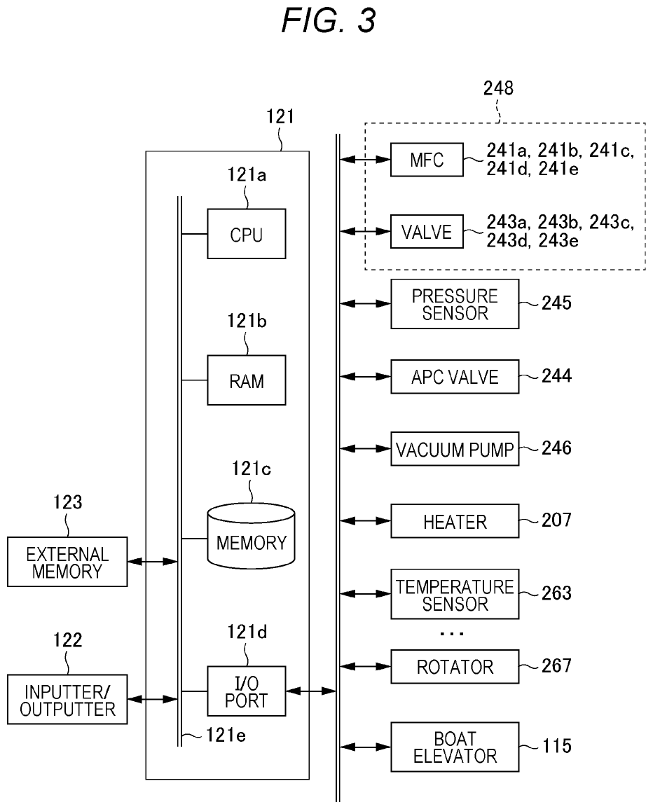

As illustrated in FIG. 3, the controller 121 serves as a computer including a central processing unit (CPU) 121a, a random access memory (RAM) 121b, a memory 121c, and an I/O port 121d. The RAM 121b, the memory 121c, and the I/O port 121d are each capable of exchanging data with the CPU 121a through an internal bus 121e. An inputter/outputter 122 serving, for example, as a touch panel is connected to the controller 121. In addition, an external memory 123 can be connected to the controller 121. Note that the substrate processing apparatus may include a single controller or may include a plurality of controllers. That is, control for a processing sequence, described later, may be performed with a single controller or with a plurality of controllers. Such a plurality of controllers may be mutually connected by a wired or wireless communication network as a control system. Control for a processing sequence, described later, may be performed by the entirety of such a control system. The term “controller” in the present specification means a single controller, a plurality of controllers, or a control system including a plurality of controllers.

The memory 121c includes, for example, a flash memory or a hard disk drive (HDD). The memory 121c stores, readably, a control program for controlling the operation of the substrate processing apparatus and a process recipe describing procedures and conditions for a substrate processing process, described later. The process recipe functions as a program for causing the controller 121 to perform each procedure in a substrate processing process, described later, to obtain a predetermined result. Hereinafter, for example, the process recipe and the control program are also collectively and simply referred to as a program. The process recipe is also simply referred to as a recipe. The term “program” in the present specification means the recipe, the control program, or both thereof. The RAM 121b serves as a memory area (work area) in which the program or data read by the CPU 121a is temporarily retained.

The I/O port 121d is connected to the MFC 241a to 241e, the valve 243a to 243e, the pressure sensor 245, the APC valve 244, the vacuum pump 246, the temperature sensor 263, the heater 207, the rotator 267, and the boat elevator 115, described above.

The CPU 121a reads the control program from the memory 121c and executes the control program, and additionally reads the recipe from the memory 121c in response to an operation command input from the inputter/outputter 122. Along the description of the read recipe, the CPU 121a can control, for example, the operations of the MFCs 241a to 241e that regulate the flow rates of various types of gas, the operations of the valves 243a to 243e that open/shut, the operation of the APC valve 244 that opens/shuts, the operation of the APC valve 244 that regulates pressure based on the pressure sensor 245, the operation of the vacuum pump 246 that starts and stops, the operation of the heater 207 that regulates temperature based on the temperature sensor 263, the operation of the rotator 267 that rotates the boat 217 and regulates the rotation rate of the boat 217, and the operation of the boat elevator 115 that raises/lowers the boat 217.

The controller 121 can be achieved due to installation of the above-described program stored in the external memory 123 into the computer. Examples of the external memory 123 include a magnetic disk such as a HDD, an optical disc such as a CD, a magneto-optical disc such as an MO, and a semiconductor memory such as a USB memory. The memory 121c and the external memory 123 each serve as a computer-readable recording medium storing the program. Hereinafter, the memories are also collectively and simply referred to as a recording medium. The term “recording medium” in the present specification means the memory 121c, the external memory 123, or both thereof. Note that the program may be provided to the computer, for example, through the Internet or a dedicated line, instead of the external memory 123.

### (2) Substrate Processing Process

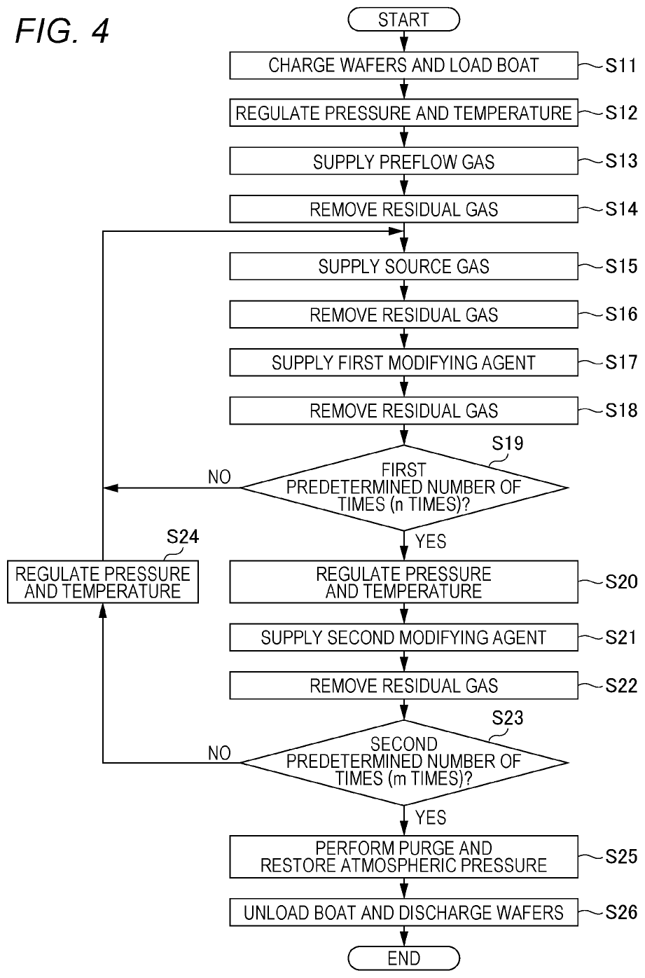

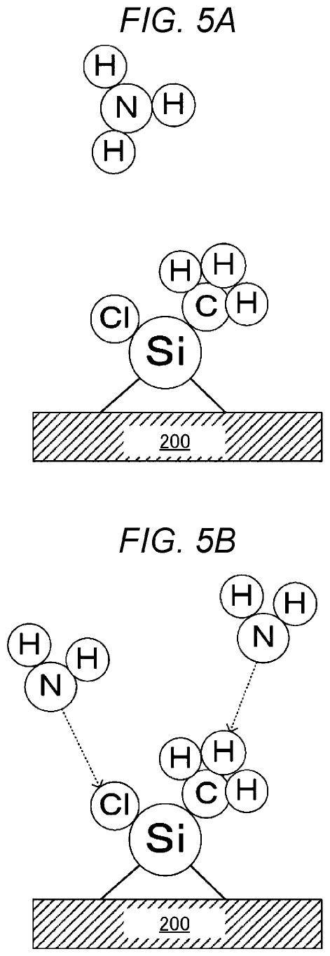

As an exemplary partial process in a process of manufacturing a semiconductor device, with the process furnace 202 of the substrate processing apparatus described above, a process of forming a first film containing a predetermined element, N, C, and H bonded to C on a wafer 200 having a surface on which a silicon film (Si film) is formed and a process of modifying the first film to a second film that is lower in the content rate of H bonded to C than the first film and contains the predetermined element, C, and N will be described mainly with FIGS. 4, 5A, and 5B. In the following description, the operation of each constituent in the substrate processing apparatus can be controlled by the controller 121.

The term “wafer” in the present specification means a wafer or a laminate of a wafer and a predetermined layer or film formed on the surface thereof. The term “surface of a wafer” in the present specification means the surface of a wafer or the surface of a predetermined layer or the like formed on a wafer. The expression “form a predetermined layer on a wafer” in the present specification means directly forming a predetermined layer on the surface of a wafer or forming a predetermined layer on a layer or the like formed on a wafer. The term “substrate” in the present specification is synonymous with the term “wafer”.

### [First-Film Forming Process (or Film-Forming Process)]

### (Wafer Charge and Boat Load in Step S11)

A plurality of wafers 200 is loaded to the boat 217 (wafer charge). After that, as illustrated in FIG. 1, the boat elevator 115 raises the boat 217 supporting the plurality of wafers 200 to load the boat 217 into the process chamber 201 (boat load). Then, the reaction tube 203 has its lower end sealed by the seal cap 219 through the O-ring 220.

### (Pressure Regulation and Temperature Regulation in Step S12)

The vacuum pump 246 vacuum-exhausts (depressurization-exhausts) the process chamber 201 such that the pressure in the process chamber 201, namely, the pressure of the space in which the wafers 200 are located fulfills a desired pressure (a desired degree of vacuum). In this case, the pressure sensor 245 measures the pressure in the process chamber 201, and the APC valve 244 is feedback-controlled based on information on the measured pressure. The vacuum pump 246 keeps operating at least until processing to the wafers 200 terminates. In addition, the heater 207 performs heating such that the wafers 200 in the process chamber 201 have a desired temperature. In this case, the degree of energization to the heater 207 is feedback-controlled based on temperature information detected by the temperature sensor 263 such that a desired temperature distribution is obtained in the process chamber 201. The heater 207 keeps heating the process chamber 201 at least until processing to the wafers 200 terminates. In addition, the rotator 267 starts to rotate the boat 217 and the wafers 200. The rotator 267 keeps rotating the boat 217 and the wafers 200 at least until processing to the wafers 200 terminates.

### (Preflow Gas Supply in Step S13)

Preflow gas is supplied to the wafers 200 in the process chamber 201. As the preflow gas, the first modifying agent that is gas containing N can be used. The first modifying agent will be described in detail later. The present step is performed as preflow to facilitate adsorption of the source gas onto the surface of each wafer 200 in step S15, described later. Specifically, the valve 243b is opened such that the first modifying agent flows in the gas supply pipe 232b. The first modifying agent is supplied into the process chamber 201 through the nozzle 249b while being regulated in flow rate by the MFC 241b and then is exhausted through the exhaust pipe 231. In this case, simultaneously, the valve 243d is opened such that the inert gas flows in the gas supply pipe 232d. Together with the first modifying agent, the inert gas is supplied into the process chamber 201 while being regulated in flow rate by the MFC 241d and then is exhausted through the exhaust pipe 231.

In addition, for prevention of the first modifying agent from entering the nozzle 249a, the valve 243c is opened such that the inert gas flows in the gas supply pipe 232c. The inert gas is supplied into the process chamber 201 through the gas supply pipe 232a and the nozzle 249a and then is exhausted through the exhaust pipe 231.

For example, gas containing a hydronitrogen-based compound is supplied as the preflow gas to the wafers 200 to nitride a native oxide layer on each wafer 200, followed by formation of a N—H terminus on each wafer 200. Thus, an increase in the density of the N—H terminus on the surface of each wafer 200 for a source adsorption site causes formation of a uniform adsorption face, leading to an improvement in film-forming rate. Preferred examples of the preflow gas used in the present step will be described later.

Examples of the inert gas that can be used include nitrogen (Ne) gas and rare gases, such as argon (Ar) gas, helium (He) gas, neon (Ne) gas, and xenon (Xe) gas. As the inert gas, one or more gases can be used from among the gases.

### (Residual Gas Removal in Step S14)

Next, the residual gas in the process chamber 201 is removed. Specifically, after formation of the N—H terminus on the surface of each wafer 200, the valve 243b is shut to stop the supply of the first modifying agent. In this case, with the APC valve 244 open and the vacuum pump 246 vacuum-exhausting the process chamber 201, the residual unreacted first modifying agent, the residual first modifying agent after contributing to the formation of the N—H terminus, and any byproduct in the process chamber 201 are eliminated from the process chamber 201. In this case, with the valves 243c and 243d open, the supply of the inert gas into the process chamber 201 is kept. The inert gas acts as purge gas.

After that, the following steps S15 to S19 are performed in order.

### (Source Gas Supply in Step S15)

In this step, the source gas is supplied into the process chamber 201. Specifically, with the APC valve 244 kept at a predetermined degree of opening, the valve 243a is opened such that the source gas flows in the gas supply pipe 232a. The source gas is supplied into the process chamber 201 through the gas supply holes 250a while being regulated in flow rate by the MFC 241a and then is exhausted through the exhaust pipe 231. In this case, the source gas is supplied to the wafers 200. In this case, simultaneously, with the valve 243c open, the inert gas flows in the gas supply pipe 232c. Together with the source gas, the inert gas is supplied into the process chamber 201 while being regulated in flow rate by the MFC 241c and then is exhausted through the exhaust pipe 231.

In addition, for prevention of the source gas from entering the nozzle 249b, with the valve 243d open, the inert gas flows in the gas supply pipe 232d. The inert gas is supplied into the process chamber 201 through the gas supply pipe 232b and the nozzle 249b and then is exhausted through the exhaust pipe 231.

Processing conditions for supply of the source gas in the present step are as follows:

Processing temperature: 150 to 800° C., preferably, 180 to 700° C., more preferably, 400 to 700° C.,

Processing pressure: 1 to 2666 Pa, preferably, 67 to 1333 Pa,

Flow rate of supply of the source gas: 1 to 2000 sccm, preferably, 10 to 1000 sccm,

Duration of supply of the source gas: 1 to 120 seconds, preferably, 1 to 60 seconds, and

Flow rate of supply of the inert gas: 100 to 10000 sccm. Note that, from the viewpoint of an improvement in processing rate, in particular, the steps in the first-film forming process are preferably substantially identical in processing temperature.

Note that the notation of a numerical range, such as “150 to 800° C.”, in the present disclosure means that the lower limit and the upper limit are included in the range. Therefore, for example, “150 to 800° C.” means “not less than 150° C. and not more than 800° C.”. The same applies to other numerical ranges. In the present disclosure, the processing temperature means the temperature of the wafers 200 or the temperature in the process chamber 201, and the processing pressure means the pressure in the process chamber 201. The duration of processing means the time during which the processing continues. The same applies to the following description.

If the temperature of the wafers 200 is less than 150° C., the source has difficulty chemically adsorbing onto each wafer 200. Thus, a practical film-forming rate may fail to be obtained. If the temperature of the wafers 200 is 150° C. or more, the above problem can be solved. If the temperature of the wafers 200 is 180° C. or more, the source can adequately adsorb onto each wafer 200. Thus, an adequate film-forming rate can be obtained. If the temperature of the wafers 200 is 400° C. or more, the source can further adequately adsorb onto each wafer 200. Thus, a further adequate film-forming rate can be obtained.

If the temperature of the wafers 200 is above 800° C., due to strong CVD reaction (dominant gas-phase reaction), a deterioration is easily made in film thickness uniformity. Thus, control is difficult in film thickness uniformity. If the temperature of the wafers 200 is 800° C. or less, deterioration can be inhibited in film thickness uniformity, enabling control in film thickness uniformity. If the temperature of the wafers 200 is 700° C. or less, due to dominant surface reaction, film thickness uniformity is easy to secure, facilitating control in film thickness uniformity.

That is, if the temperature of the wafers 200 is, for example, 150 to 800° C. in the present process, the source adsorbs onto each wafer 200, leading to an improvement in film-forming rate and an improvement in film thickness uniformity. Excessive gas-phase reaction can be inhibited from occurring, leading to inhibition of particles from being produced.

Due to supply of the source gas to the wafers 200, for example, a first layer having a thickness ranging approximately from less than the thickness of a monolayer to the thickness of several atomic layers and containing the predetermined element, C, and H is formed on each wafer 200 having the N—H terminus formed on its surface. That is, in a case where gas containing Si serving as the predetermined element, C, and H is used as the source gas, the first layer contains H originating from the source, in addition to Si—C bonds. H in the first layer achieves bonds, such as C—H bonds and Si—H bonds. A Si-containing layer containing C and H corresponds to a layer containing Si—C bonds, Si—H bonds, and C—H bonds. Such a Si-containing layer containing C and H may be a Si layer containing C and H, an adsorption layer of the source gas, or include both thereof.

“Si layer containing C and H” is a generic term for a continuous Si layer containing C and H, a discontinuous Si layer containing C and H, and a Si thin film containing C and H and including such Si layers overlaid each other. Such a continuous Si layer containing C and H is also referred to as a Si thin film containing C and H. Examples of Si in a Si layer containing C and H include Si having an incomplete bond with C or H and Si having no bond with C or H.

Examples of such an adsorption layer of the source gas include a continuous adsorption layer of molecules of the source gas and a discontinuous adsorption layer of molecules of the source gas. That is, examples of an adsorption layer of the source gas include an adsorption layer of molecules of the source gas with a thickness identical to or less than the thickness of one molecular layer.

A layer having a thickness less than the thickness of a monolayer means a discontinuously formed atomic layer. A layer having a thickness identical to the thickness of a monolayer means a continuously formed atomic layer. A layer having a thickness less than the thickness of one molecular layer means a discontinuously formed molecular layer. A layer having a thickness identical to the thickness of one molecular layer means a continuously formed molecular layer.

Under condition that the source gas autolyzes (e.g., becomes pyrolyzed), for example, when Si is deposited on each wafer 200, a Si layer containing C and H is formed. Under condition that the source gas does not autolyze, when the source gas adsorbs onto each wafer 200, an adsorption layer of the source gas is formed. Even under both of the conditions, at least part of bonds, such as Si—C bonds, Si—H bonds, and C—H bonds, in the source gas is retained (kept) without being broken and is taken in a Si-containing layer containing C and H.

As the source gas, gas containing the predetermined element, C, and H can be used. As such gas containing the predetermined element, C, and H, for example, gas containing Si serving as the predetermined element, C, and H can be used. As such gas containing Si, C, and H, for example, gas containing a hydrocarbon group, namely, a compound containing C—H bonds, such as alkylsilane gas or alkylenesilane gas.

As such gas containing the predetermined element, C, and H, gas containing the predetermined element, C, H, and a halogen element can be used. As such gas containing the predetermined element, C, H, and a halogen element, for example, gas containing Si serving as the predetermined element, C, H, and chlorine (Cl) serving as the halogen element can be used. Examples of such gas containing Si, C, H, and Cl that can be used include alkylene halosilane gas containing Si, an alkylene group, and a halogen group and including chemical bonds of Si and C (Si—C bonds) and alkyl halosilane gas containing Si, an alkyl group, and a halogen group and including Si—C bonds.

Such an alkylene group is a functional group resulting from removal of two atoms of H from chain saturated hydrocarbon (alkane) expressed by the general formula CₙH₂ₙ₊₂, namely, an aggregate of atoms expressed by the general formula CₙH₂ₙ. Examples of the alkylene group include a methylene group, an ethylene group, a propylene group, and a butylene group. Such an alkyl group is a functional group resulting from removal of one atom of H from chain saturated hydrocarbon expressed by the general formula CₙH₂ₙ₊₂, namely, an aggregate of atoms expressed by the general formula CₙH₂ₙ₊₁. Examples of the alkyl group include a methyl group, an ethyl group, a propyl group, and a butyl group. Examples of such a halogen group include a chloro group, a fluoro group, and a bromo group. That is, the halogen group includes halogen elements, such as chlorine (Cl), fluorine (F), and bromine (Br).

Examples of alkylene halosilane gas that can be used include gas containing Si, the methylene group (—CH—) serving as the alkylene group, and the chloro group (Cl) serving as the halogen group, namely, chlorosilane gas containing the methylene group, and gas containing, Si, the ethylene group (—C₂H₄—) serving as the alkylene group, and the chloro group (Cl) serving as the halogen group, namely, chlorosilane gas containing the ethylene group. Examples of chlorosilane gas containing the methylene group that can be used include methylenebis (trichlorosilane) gas, namely, bis (trichlorosilyl) methane ((SiCl₃)₂CH₂, abbreviation: BTCSM) gas. Examples of chlorosilane gas containing the ethylene group that can be used include ethylenebis (trichlorosilane) gas, namely, 1,2-bis (trichlorosilyl) ethane ((SiCl₃)₂C₂H₄, abbreviation: BTCSE) gas.

Examples of alkyl halosilane gas that can be used include gas containing Si, the methyl group (—CH₃) serving as the alkyl group, and the chloro group (Cl) serving as the halogen group, namely, chlorosilane gas containing the methyl group. Examples of chlorosilane gas containing the methyl group that can be used include 1,1,2,2-tetrachloro-1,2-dimethyldisilane ((CH₃)₂Si₂Cl₄, abbreviation: TCDMDS) gas, 1,2-dichloro-1,1,2,2-tetramethyldisilane ((CH₃)₄Si₂Cl₂, abbreviation: DCTMDS) gas, and 1-monochloro-1,1,2,2,2-pentamethyldisilane ((CH₃)₅Si₂Cl, abbreviation: MCPMDS) gas. Alkyl halosilane gas, such as TCDMDS gas, DCTMDS gas, or MCPMDS gas, corresponds to gas including Si—Si bonds, namely, the source gas containing the predetermined element and a halogen element and including chemical bonds of atoms of the predetermined element, differently from alkylene halosilane gas, such as BTCSE gas, or BTCSM gas.

Alkylene halosilane gas, such as BTCSM gas or BTCSE gas, and alkyl halosilane gas, such as TCDMDS gas, DCTMDS gas, or MCPMDS gas, can be regarded as the source gas containing at least two atoms of Si per molecule and Cl and including Si—C bonds and C—H bonds. Such gases act as a Si source or a C source in the present process. For example, BTCSM gas and BTCSE gas can be referred to as alkylene chlorosilane gas. For example, TCDMDS gas, DCTMDS gas, and MCPMDS gas can be referred to as alkyl chlorosilane gas.

In a case where gas containing the predetermined element, C, H, and a halogen element is used as the source gas, the first layer may contain, as impurities, the halogen element originating from the source gas, in addition to the predetermined element, C, and H. For example, in a case where the source gas contains Cl as the halogen element, the first layer further contains bonds such as Si—Cl bonds.

### (Residual Gas Removal in Step S16)

Next, the residual gas in the process chamber 201 is removed. Specifically, after formation of the first layer, the valve 243a is shut to stop the supply of the source gas. In this case, with the APC valve 244 open and the vacuum pump 246 vacuum-exhausting the process chamber 201, the residual unreacted source gas, the residual source gas after contributing to the formation of the first layer, and any byproduct in the process chamber 201 are eliminated from the process chamber 201. In this case, the valves 243c and 243d open, the supply of the inert gas into the process chamber 201 is kept. The inert gas acts as purge gas.

### (First Modifying Agent Supply in Step S17)

Next, the first modifying agent is supplied to the wafers 200 in the process chamber 201.

Specifically, similarly to step S13 described above, the valve 243b is opened such that the first modifying agent flows in the gas supply pipe 232b. The first modifying agent is supplied into the process chamber 201 through the nozzle 249b while being regulated in flow rate by the MFC 241b and then is exhausted through the exhaust pipe 231. In this case, simultaneously, with the valve 243d open, the inert gas flows in the gas supply pipe 232d. Together with the first modifying agent, the inert gas is supplied into the process chamber 201 while being regulated in flow rate by the MFC 241d and then is exhausted through the exhaust pipe 231.

In addition, for prevention of the first modifying agent from entering the nozzle 249a, with the valve 243c open, the inert gas flows in the gas supply pipe 232c. The inert gas is supplied into the process chamber 201 through the gas supply pipe 232a and the nozzle 249a and then is exhausted through the exhaust pipe 231.

Processing conditions for supply of the first modifying agent in the present step are as follows:
Processing pressure: 1 to 4000 Pa, preferably, 10 to 1000 Pa,
Flow rate of supply of the first modifying agent: 0.1 to 20 slm, preferably, 1 to 10 slm,
Duration of supply of the first modifying agent: 1 to 120 seconds, preferably, 10 to 60 seconds, and
Flow rate of supply of the inert gas: 0 to 10 slm. The other processing condition can be made similar to that of the processing conditions for supply of the source gas in the source gas supply step.

N-containing gas can be used as the first modifying agent. Examples of such N-containing gas that can be used include nitrogen (N₂) gas, hydronitrogen-based gases, such as ammonia (NH₃) gas, diazene (N₂H₂) gas, hydrazine (N₂H₄) gas, and N₃H₅ gas. As the N-containing gas, one or more gases can be used from among the gases.

Note that, as described later, in the present step, preferably, as the first modifying agent, used is gas containing a hydronitrogen-based compound containing N but no bond of atoms of N per molecule, namely, no N—N bond per molecule. Examples of such gas containing a hydronitrogen-based compound containing N but no bond of atoms of N per molecule, namely, no N—N bond per molecule that can be used include NH₃ gas.

The first modifying agent used in step S13 for preflow gas supply described above may be different from the first modifying agent used in the present step. For example, in the preflow gas supply step, gas containing a hydronitrogen-based compound containing N and a bond of atoms of N per molecule, namely, an N—N bond per molecule may be used, and in the present step, gas containing a hydronitrogen-based compound containing N but no bond of atoms of N per molecule, namely, no N—N bond per molecule may be used. For example, in the preflow gas supply step, the second modifying agent, described later, may be supplied as the preflow gas.

Due to supply of the first modifying agent containing N to the wafers 200, at least part of the first layer formed on each wafer 200 is nitrided (modified). Due to modification of the first layer, for example, formed is a second layer containing impurities, such as H and Cl remaining in the first layer, in addition to Si—C bonds, Si—N bonds, and C—N bonds. H in the second layer achieves bonds, such as C—H bonds, Si—H bonds, and N—H bonds. That is, due to use of the first modifying agent, the first layer containing the predetermined element, C, and H is modified to the second layer containing the predetermined element, C, H, and N, leading to formation of a silicon carbonitride layer (SiCN layer), for example.

Due to supply of the first modifying agent, part of H and Cl in the first layer desorbs but H and Cl, of which the concentrations are each above a desired concentration, remain in the second layer. If impurities, such as H and Cl, of which the concentrations are each above the desired concentration, remain in the film, a reduction is likely to be made in film density, leading to a deterioration in ashing resistance.

In the present step, in a case where gas containing a hydronitrogen-based compound high in reactivity like the second modifying agent described later in detail or gas containing a derivative thereof is used, during nitriding reaction until the concentration of N in the first layer reaches a desired concentration, C in the first layer is likely to desorb excessively. That is, the concentration of C in the second layer may fail to be kept at a desired concentration. Therefore, favorably, gas containing a hydronitrogen-based compound low in reactivity is used as the first modifying agent in the present step. Examples of such gas containing a hydronitrogen-based compound low in reactivity that can be used include gas containing a hydronitrogen-based compound containing N but no bond of atoms of N per molecule, namely, no N—N bond per molecule, as described above.

Preferably, the first modifying agent is thermally activated in a non-plasma and then is supplied because the reaction described above can be made gentle, leading to facilitation of formation of the second layer. In forming the second layer, impurities, such as Cl, in the first layer achieve a gaseous substance containing at least Cl during the modification reaction of the first layer due to the first modifying agent and then the gaseous substance is discharged from the process chamber 201. That is, impurities, such as Cl, in the first layer separate from the first layer due to extraction or desorption from the first layer. Thus, the second layer is less than the first layer in terms of impurities, such as Cl.

### (Residual Gas Removal in Step S18)

Next, the residual gas in the process chamber 201 is removed. Specifically, after formation of the second layer, the valve 243b is shut to stop the supply of the first modifying agent. In this case, with the APC valve 244 open and the vacuum pump 246 vacuum-exhausting the process chamber 201, the residual unreacted first modifying agent, the residual first modifying agent after contributing to the formation of the second layer, and any byproduct in the process chamber 201 are eliminated from the process chamber 201. In this case, with the valves 243c and 243d open, the supply of the inert gas into the process chamber 201 is kept. The inert gas acts as purge gas.

### (First Predetermined Number of Times of Performance in Step S19)

A cycle in which steps S15 to S18 described above are performed asynchronously is performed a first predetermined number of times (n times, n is an integer of 1 or more). Thus, a first film containing the predetermined element, N, C, and H bonded to C (namely, C—H bonds) is formed on each wafer 200. The cycle described above is preferably performed a plurality of times until the first film has a desired thickness. As the first film, for example, a silicon carbonitride film (SiCN film) containing Si, N, C, and C—H bonds can be formed.

In this case, for example, the thickness of the first film is set at 10 to 200 Å, preferably, 10 to 100 Å. If the thickness of the first film is less than 10 Å, a film having a desired property may fail to be obtained. If the thickness of the first film is 10 Å or more, a film having a desired property can be obtained. If the thickness of the first film is more than 200 Å, a modification effect in a modification process described later may fail to work adequately over the entirety in the thickness direction of the first film. If the thickness of the first film is 200 Å or less, the modification effect in the modification process described later can work over the entirety in the thickness direction of the first film. If the thickness of the first film is 100 Å or less, the modification effect in the modification process described later can work more reliably over the entirety in the thickness direction of the first film.

The first film contains impurities, such as H and Cl remaining based on the first layer, in addition to Si—C bonds, Si—N bonds, and C—N bonds. H in the first film achieves bonds, such as C—H bonds, Si—H bonds, and N—H bonds. Such C—H bonds, Si—H bonds, and N—H bonds remaining in the film cause a deterioration in ashing resistance. However, for an improvement in ashing resistance, in a case where plasma processing is performed to the first film to remove impurities, such as H and Cl, not only the impurities, such as H and Cl, but also C is likely to desorb from the film. Thus, in the present embodiment, for inhibition of C from desorbing from the film and reduction of the impurities, such as H and Cl, after the film-forming process described above, the following modification process is performed.

In the present embodiment, after formation of the first film in the film-forming process (steps S12 to S19) described above, the following modification process (steps S20 to S22) is performed without exposing the wafers 200 to an oxygen-containing atmosphere. In a case where the wafers 200 are exposed to an oxygen-containing atmosphere after formation of the first film, an oxide layer is likely to be formed on the surface of the first film. If an oxide layer is formed on the surface of the first film, a modification effect, namely, an effect of reducing, for example, H in the depth direction of the first film in step S21 described later is hindered. Thus, an adequate modification effect may fail to be obtained. That is, after the first-film forming process, the following second-film forming process is performed without exposure to an oxygen-containing atmosphere, leading to an improvement in modification effect in step S21. That is, with no oxide layer on the surface of the first film, the following second-film forming process is performed.

The second-film forming process is performed after the space in which the wafers 200 are located is purged (also referred to as inert gas purging) due to removal of the residual gas in step S18 after supply of the first modifying agent in step S17 in the first-film forming process. That is, the space in which the wafers 200 are located is purged after the film-forming process but before the modification process. Thus, before the modification process, the impurities, such as Cl, can be removed to some extent.

### [Second-Film Forming Process (or Modification Process)]

### (Pressure Regulation and Temperature Regulation in Step S20)

The vacuum pump 246 vacuum-exhausts the process chamber 201 such that the pressure in the process chamber 201 fulfills a desired pressure. In addition, the heater 207 performs heating such that the wafers 200 in the process chamber 201 have a desired temperature.

### (Second Modifying Agent Supply in Step S21)

Next, the second modifying agent is supplied to the wafers 200 each having the first film formed thereon. Specifically, the valve 243e is opened such that the second modifying agent flows in the gas supply pipe 232e. The second modifying agent is supplied into the process chamber 201 through the nozzle 249b while being regulated in flow rate by the MFC 241e and then is exhausted through the exhaust pipe 231. In this case, simultaneously, with the valve 243d open, the inert gas flows in the gas supply pipe 232d. Together with the second modifying agent, the inert gas is supplied into the process chamber 201 while being regulated in flow rate by the MFC 241d and then is exhausted through the exhaust pipe 231.

In addition, for prevention of the second modifying agent from entering the nozzle 249a, with valve 243c open, the inert gas flows in the gas supply pipe 232c. The inert gas is supplied into the process chamber 201 through the gas supply pipe 232a and the nozzle 249a and then is exhausted through the exhaust pipe 231.

Processing conditions for supply of the second modifying agent in the present step are as follows:
Processing temperature: room temperature to 700° C., preferably, 150 to 700° C., more preferably, 150 to 400° C.,
Processing pressure: 1 to 2666 Pa, preferably, 67 to 1333 Pa,
Flow rate of supply of the second modifying agent: 1 to 2000 sccm, preferably, 10 to 1000 sccm,
Duration of supply of the second modifying agent: 1 to 120 seconds, preferably, 1 to 60 seconds, and
Flow rate of supply of the inert gas: 0 to 10000 sccm. Note that, from the viewpoint of an improvement in processing rate, the processing temperature in the present step is preferably substantially identical to the processing temperature in the first-film forming process.

If the temperature of the wafers 200 is less than the room temperature, the second modifying agent is hardly activated. Thus, in modifying the first film, an adequate modification effect may fail to be obtained. If the temperature of the wafers 200 is not less than the room temperature, the second modifying agent is activated, so that modification action can work over the entirety in the thickness direction of the first film. If the temperature of the wafers 200 is 150° C. or more, the second modifying agent is further activated, so that modification action can work reliably over the entirety in the thickness direction of the first film.

If the temperature of the wafers 200 is above 700° C., the second modifying agent becomes pyrolyzed excessively. Thus, no modification effect may be obtained to the first film. For example, in a case where N₂H₄ is used as the second modifying agent, when N₂H₄ becomes pyrolyzed excessively, NH₃ low in reactivity is produced from the second modifying agent, instead of NH₂ that is an intermediate high in reactivity. Thus, no modification effect may be obtained to the first film. If the temperature of the wafers 200 is above 400° C., the second modifying agent becomes pyrolyzed partially. Because of a similar reason, a deterioration is likely to be made in modification effect to the first film. If the temperature of the wafers 200 is 700° C. or less, a modification effect can be obtained. If the temperature of the wafers 200 is 400° C. or less, a modification effect can be reliably obtained.

In a case where the temperature of the wafers 200 in the present process is set in the range of the room temperature to 700° C., the reactivity of the second modifying agent can be controlled easily such that the second modifying agent or an intermediate thereof reacts with H bonded to C, H bonded to Si, or Cl bonded to Si in the first film to cause H and Cl to desorb with C inhibited from desorbing.

Note that, in a case where the temperature of the wafers 200 in the present process is set lower than the temperature of the wafers 200 in the first-film forming process described above, the reactivity of at least one of the second modifying agent and an intermediate thereof can be controlled easily with regulation of the degrees of pyrolysis and activation of the second modifying agent. Therefore, the reactivity of the second modifying agent can be controlled more easily such that H bonded to C desorbs with C inhibited from desorbing from the first film. In a case where the present process is performed at low temperature, the influence of thermal hysteresis can be reduced to the wafers 200 in the present process. On the other hand, in a case where the processing temperature is substantially identical to the processing temperature in the first-film forming process, an improvement can be made in processing rate to the wafers 200.

In this case, the partial pressure of the second modifying agent is smaller than the partial pressure of the first modifying agent in step S17 described above. In this case, the flow rate of the second modifying agent may be smaller than the flow rate of the first modifying agent in step S17 described above. Thus, the reaction rate of the second modifying agent higher in reactivity than the first modifying agent can be controlled easily.

In a case where the first film is modified with a plasma-excited second modifying agent, for example, because radicals produced due to plasma excitation have excessively high reactivity, the radicals cause not only H bonded to C but also C bonded to the predetermined element or N in the film to desorb. In the present disclosure, the second modifying agent high in reactivity than the first modifying agent is supplied, in a non-plasma, to the wafers 200. Thus, for example, H bonded to C can be selectively desorbed with C inhibited from desorbing.

Examples of the second modifying agent that can be used include gas containing a hydronitrogen-based compound containing a bond of N and H (namely, a N—H bond) and a bond of N and N (namely, a N—N bond) per molecule and gas containing a derivative thereof.

As the second modifying agent, for example, used can be gas containing at least one compound of diazene (N₂H₂), hydrazine (N₂H₄), triazene (N₃H₃), and triazane (N₃H₅) each serving as a hydronitrogen-based compound containing a N—H bond and a N—N bond per molecule. As the second modifying agent, for example, used can be gas containing a derivative, such as monomethylhydrazine (CH₃(NH)NH₂), 1,1-dimethylhydrazine (unsymmetrical dimethylhydrazine) ((CH₃)₂—N—NH—), or 1,2-dimethylhydrazine (tetramethylhydrazine) (N₂(CH₃)₄), serving as a derivative of a hydronitrogen-based compound containing a N—H bond and a N—N bond per molecule. As the second modifying agent, one or more gases can be used from among the gases.

### (Residual Gas Removal in Step S22)

Next, the residual gas in the process chamber 201 is removed. Specifically, after formation of the second film resulting from modification of the first film, the valve 243e is shut to stop the supply of the second modifying agent. In this case, with the APC valve 244 open and the vacuum pump 246 vacuum-exhausting the process chamber 201, the residual unreacted second modifying agent, the residual second modifying agent after contributing to the modification of the first film, and any byproduct in the process chamber 201 are eliminated from the process chamber 201. In this case, with the valves 243c and 243d open, the supply of the inert gas into the process chamber 201 is kept. The inert gas acts as purge gas.

Due to supply of the second modifying agent in a non-plasma to the wafers 200, at least part of the first film formed on each wafer 200 is nitrided (modified), resulting in being closely densified. Due to modification of the first film, for example, the second film containing Si, C, and N, namely, a SiCN film is formed on each wafer 200. Preferably, the second modifying agent is thermally activated in a non-plasma and then is supplied because the reaction described above can be made gentle, leading to facilitation of formation of the second film. In forming the second film, impurities, such as H and Cl, in the first film achieve a gaseous substance containing at least H and Cl and then the gaseous substance is discharged from the process chamber 201 in the present process. That is, the first film is modified with the second modifying agent higher in reactivity than the first modifying agent described above to C—H bonds, Si—H bonds, and N—H bonds in the first film. Thus, an intermediate of the second modifying agent reacts with H or Cl in the C—H bonds, Si—H bonds, and N—H bonds in the first film, so that H or Cl desorb from the first film. That is, impurities, such as H and Cl, desorb with the concentration of C in the first film kept in a desired range. In other words, the first film on each wafer 200 can be modified to the second film that is lower in the content rate of H bonded to C than the first film and contains the predetermined element, C, and N.

Such reduction of the impurities, such as H and Cl, in the film enables an improvement in the ashing resistance of the film. The concentration of C in the film kept in the desired range enables an improvement in the etching resistance of the film. That is, such modification with the second modifying agent as above enables the first film to be modified to the second film with a balance between ashing resistance and etching resistance.

### (Second Predetermined Number of Times of Performance in Step S23)

In the present step, in a case where the number of times a cycle in which steps S15 to S22 are performed asynchronously has been performed is less than a second predetermined number of times (m times, m is an integer of 1 or more), in accordance with a procedure similar to the procedure of step S12 described above, regulation is performed such that the pressure in the process chamber 201 and each wafer 200 in the process chamber 201 fulfill, respectively, the predetermined pressure and the predetermined temperature in the first-film forming process described above (step S24). Then, the processing goes back to step S15 described above. A cycle including steps S15 to S22 is performed the second predetermined number of times, so that a film containing the predetermined element, C, and N and having a desired thickness can be formed on each wafer 200. That is, in the present embodiment, a cycle including the film-forming process (excluding the preflow gas supply step) and the modification process is performed the second predetermined number of times, leading to formation of a film containing the predetermined element, C, and N and having a desired thickness onto each wafer 200. Note that the preflow gas supply step may be performed per present cycle, instead of one time before the present cycle as in the present embodiment.

Every time the above-described cycle in which steps S15 to S18 are performed asynchronously is performed a plurality of times, steps S20 to S22 are performed one time, leading to an improvement in throughput with a reduction in the number of times of performance of steps S20 to S22.

In the present modification process (second-film forming process), the first film is modified to the second film such that a reduction in the content rate of H in the first film is larger than a reduction in the content rate of C in the first film. That is, in the present process, the first film is modified to the second film such that a reduction is made in the content rate of H with inhibition of a reduction in the content rate of C.

FIG. 5A illustrates the state of the surface of a wafer 200 in a case where NH₃ gas is supplied to the first film formed on the wafer 200. FIG. 5B illustrates the state of the surface of a wafer 200 in a case where N₂H₄ gas is supplied to the first film formed on the wafer 200.

As illustrated in FIG. 5A, NH₃ includes N—H bonds relatively large in activation energy and thus has difficulty becoming pyrolyzed to intermediates high in reactivity. NH₃ needs a large activation energy to react with a C—H bond, a Si—H bond, or a Si—Cl remaining in the first film and thus has difficulty reacting to break such a bond. That is, NH₃ is insufficient to remove such bonds in the first film. For example, the activation energy (Ea(H)) for NH₃ to react with a Si—H bond in the first film to desorb H is 1.95, and the activation energy (Ea(Cl)) for NH₃ to react with a Si—Cl bond in the first film to desorb Cl is 1.33.

On the other hand, as illustrated in FIG. 5B, N₂H₄ contains a N—N bond relatively small in activation energy and thus becomes pyrolyzed easily to intermediates NH-high in reactivity. Such an intermediate NH-contains N having a dangling bond. Thus, a small activation energy is enough for the intermediate NH₂ to react with a C—H bond, a Si—H bond, or a Si—Cl bond remaining in the first film. Thus, the intermediate NH₂ reacts easily to break such a bond. That is, N₂H₄ (intermediate NH) is strong enough to remove such bonds in the first film. According to exemplary results of calculation of molecular simulation by the inventors, the activation energy (Ea(H)) for NH₂ to react with a Si—H bond in the first film to desorb H is 0.01, and the activation energy (Ea(Cl)) for NH to react with a Si—Cl bond in the first film to desorb Cl is 0.16.

That is, the activation energy for an intermediate NH—, produced due to decomposition of N₂H₄ serving as an example of the second modifying agent, to react with H bonded to C in the first film to desorb H is smaller than the activation energy for NH₃ serving as an example of the first modifying agent to desorb H bonded to C in the first film. That is, when NH₂ that is an intermediate of N₂H₄ higher in reactivity than NH₃ reacts with H bonded to C in the first film, H can desorb from the first film.

The activation energy for NH to react with Cl bonded to Si in the first film to desorb Cl is smaller than the activation energy for NH₃ to desorb Cl bonded to Si in the first film. That is, when NH₂ that is an intermediate of N₂H₄ higher in reactivity than NH₃ reacts with Cl bonded to Si in the first film, Cl can desorb from the first film.

That is, in the present modification process, the first film is modified with the second modifying agent, so that the first film is modified to the second film such that reductions are made in the content rates of H bonded to the predetermined element, H bonded to C, and H bonded to N in the first film. That is, reductions are made in the content rates (concentrations) of H bonded, for example, to Si, H bonded to C, and H bonded to N in the first film. Specifically, due to supply of the second modifying agent, such intermediates produced from the second modifying agent as described above react with, for example, Si—H bonds, C—H bonds, and N—H bonds in the first film to desorb H from the first film. A reduction in the content rate of H in the film enables an improvement in film property, such as ashing resistance.

In the present process, the first film is modified to the second film to desorb Cl that is an exemplary halogen element in the first film. That is, reductions are made in the content rates of Cl bonded to C, Cl bonded to Si, and Cl bonded to N, remaining in the first film. Specifically, due to supply of the second modifying agent, such intermediates produced from the second modifying agent as described above react with C—Cl bonds, Si—Cl bonds, and N—Cl bonds in the first film to desorb Cl from the first film. A reduction in the content rate of the halogen element, such as Cl, in the film enables an improvement in film property, such as ashing resistance.

The concentration of H in the first film before the modification process is, for example, 20 to 30 atomic %, and the concentration of H in the second film after the modification process is, for example, 0 to 10 atomic %. In a case where the concentration of H in the second film is above 10 atomics, a practical range of ashing resistance may fail to be obtained. If the concentration of H in the second film is 10 atomic % or less, the ashing resistance of the second film to plasma ashing with oxygen (O₂) plasma can be improved to a practical range.

The concentration of C in the second film after the modification process is kept in a desired range in which etching resistance is kept, for example, in a range of 5 to 30 atomic %, preferably, in a range of 10 to 30 atomic %.

In a case where the concentration of C in the second film is less than 5 atomic %, a considerable reduction is likely to be made in etching resistance. If the concentration of C in the second film is 5 atomic % or more, an improvement can be made in the etching resistance of the second film to wet etching with a diluted hydrogen fluoride (HF) aqueous solution, for example. If the concentration of C in the second film is 10 atomic % or more, the etching resistance of the second film can be improved to a practical range.

In a case where the concentration of C in the second film is above 30 atomic %, a practical range of etching resistance may fail to be obtained. If the concentration of C in the second film is 30 atomic % or less, the etching resistance of the second film can be improved to a practical range.

That is, according to the present embodiment, a modification can be made such that the concentration of C and the concentration of H in the film fulfill the respective desired ranges described above, leading to formation of a film with a balance between ashing resistance and etching resistance.

### (Purge and Atmospheric Pressure Restoration in Step S25)

The valves 243c and 243d are opened such that the inert gas is supplied into the process chamber 201 through each of the gas supply pipes 232c and 232d and then is exhausted through the exhaust pipe 231. The inert gas acts as purge gas. Thus, the process chamber 201 is purged internally, so that the residual gas and any byproduct in the process chamber 201 are removed from the process chamber 201 (purge). After that, the atmosphere in the process chamber 201 is replaced with the inert gas (inert gas replacement), so that the pressure in the process chamber 201 is restored to normal pressure (atmospheric pressure restoration).

### (Boat Unload and Wafer Discharge in Step S26)

The boat elevator 115 lowers the seal cap 219, so that the opening at the lower end of the reaction tube 203 is exposed. Then, the processed wafers 200 having been supported by the boat 217 are unloaded outward through the opening at the lower end of the reaction tube 203 (boat unload). The processed wafers 200 are discharged from the boat 217 (wafer discharge).

### (3) Effects According to Present Embodiment

According to the present embodiment, one or a plurality of effects below can be obtained.

(a) A film high in film density and high in ashing resistance with fewer impurities, such as H and Cl, can be formed.

(b) A film high in etching resistance with fewer impurities, such as H and Cl, and with the concentration of C kept in a desired range can be formed.

(c) That is, a film formed on a wafer 200 can be modified to a film having a balance between ashing resistance and etching resistance.

(d) The above effects can be obtained not only for formation and modification of a SiCN film but also for formation and modification of any other CN-containing film.

### Other Embodiments of Present Disclosure

At least one embodiment of the present disclosure has been specifically described above. However, the present disclosure is not limited to the above embodiment, and thus various modifications can be made without departing from the gist thereof.

### Modified Example

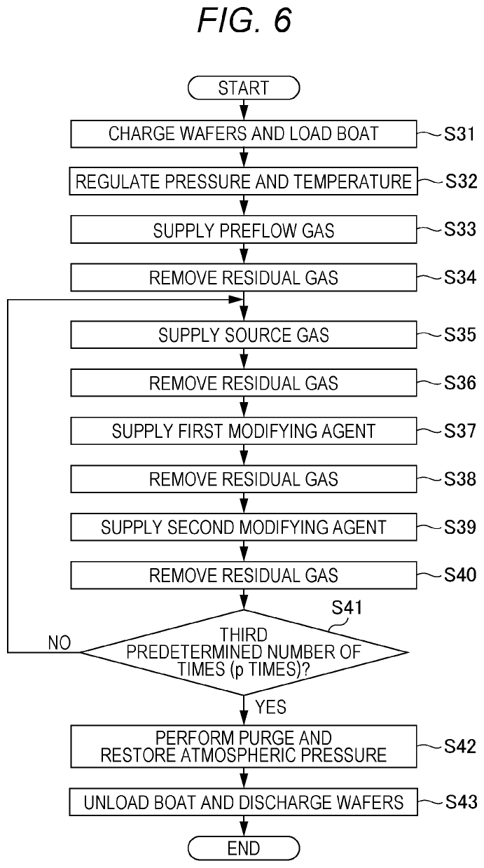

Next, a modified example of the substrate processing process described above will be described with FIG. 6.

In the present modified example, such a film-forming process as described above includes a modification process. That is, after steps S31 to S38 similar in processing to steps S11 to S18 described above, steps S39 and S40 similar in processing to steps S21 and S22 in the modification process described above are performed. Then, as step S41, a cycle in which steps S35 to S40 are performed is performed a third predetermined number of times (p times, p is an integer of 1 or more).

Due to the third predetermined number of times of performance of the cycle, a third film having a desired thickness and having fewer impurities, such as H and Cl, with the concentration of C kept in a desired range can be formed, similarly to the second film described above. That is, according to the present modified example, effects similar to those in the embodiment described above can be obtained. Furthermore, according to the present modified example, modification processing to remove H and Cl is performed every time a first film formed on the surface of each wafer 200 is grown, so that an improvement can be made in film-forming rate, namely, in the rate of forming the first film, with an increase in the density of a N—H terminus on the surface of each wafer 200 for a source adsorption site. In addition, with a shorter duration of processing, an improvement can be made in throughput.

### OTHER EMBODIMENTS

For example, in the embodiment described above, given has been an exemplary case where the predetermined element in the source gas is Si. However, the present disclosure is not limited to such an embodiment. For example, the predetermined element may be a metallic element, such as titanium (Ti), zirconium (Zr), hafnium (Hf), tantalum (Ta), niobium (Nb), aluminum (Al), molybdenum (Mo), tungsten (W), or germanium (Ge). In such a case, a metal-based carbonitride film is formed, such as a titanium carbonitride film (TiCN film), a zirconium carbonitride film (ZrCN film), a hafnium carbonitride film (HfCN film), a tantalum carbonitride film (TaCN film), a niobium carbonitride film (NbCN film), an aluminum carbonitride (AlCN film), a molybdenum carbonitride film (MoCN film), a tungsten carbonitride film (WCN film), or a germanium carbonitride film (GeCN film). Even in the case, effects similar to those in the embodiment described above can be obtained.

In the embodiment described above, given has been a case where, in the film-forming process, the first film containing the predetermined element, N, C, and H bonded to C is formed on each wafer 200 having a Si film formed on its surface. However, the present disclosure is not limited to this and thus can be favorably applied to a case where the first film is formed on each wafer 200 having an oxide film, such as a silicon oxide film (SiO film), or a nitride film, such as a silicon nitride film (SiN film), formed on its surface or a case where the first film is formed on the surface of each wafer 200.

In the embodiment described above, given has been a case where the first-film forming process and the modification process are performed continuously in the same process chamber 201 (in-situ). The present disclosure is not limited to this, and thus the first-film forming process and the modification process may be performed separately in respective different process chambers (process containers) (ex-situ). Even in this case, effects similar to those in the embodiment described above can be obtained. Note that, if the processes are performed in-situ, the substrates can be inhibited from being contaminated and the state of the surface of each substrate can be inhibited from being changed because of no unloading of the substrates outward from the process chamber between the processes and no loading of the substrates from outside the process chamber between the processes. In addition, if the processes are performed in-situ, the duration of transition between the processes is shorter. On the other hand, if the processes are performed ex-situ, the processes can be performed in parallel in different process chambers. Due to the processes in parallel, an enhancement can be made in productivity.

Note that, favorably, individual recipes corresponding to types of processing are prepared for substrate processing and then are stored in the memory 121c through a telecommunication line or the external memory 123. Then, favorably, at the start of substrate processing, the CPU 121a appropriately selects, from the plurality of recipes stored in the memory 121c, a proper recipe corresponding to the type of processing. Thus, various types of films, films having various composition ratios, various types of quality of films, or films having various thicknesses can be formed reproducibly with a single substrate processing apparatus. In addition, an operator can start substrate processing properly with its burden reduced and without any operation errors.

Such a recipe as described above is not limited to a new created recipe and thus may be prepared, for example, due to a change in an existing recipe installed in advance on the substrate processing apparatus. In a case where a change is made in a recipe, the changed recipe may be installed onto the substrate processing apparatus through a telecommunication line or a recording medium on which the recipe is recorded. In addition, the inputter/outputter 122 in the existing substrate processing apparatus may be operated to directly make a change in an existing recipe installed in advance on the substrate processing apparatus.

In the embodiment described above, given has been exemplary processing of a film with a batch type of substrate processing apparatus that processes a plurality of substrates at a time. The present disclosure is not limited to the embodiment described above and thus can be favorably applied, for example, to a case where a film is processed with a single-wafer type of substrate processing apparatus that processes a single substrate or several substrates at a time. In the embodiment described above, given has been exemplary processing of a film with a substrate processing apparatus including a hot wall type of process furnace. The present disclosure is not limited to the embodiment described above and thus can be favorably applied to a case where a film is processed with a substrate processing apparatus including a cold wall type of process furnace.

Even with either of the substrate processing apparatuses, film-forming processing can be performed based on processing procedures and processing conditions similar to those in the embodiment described above, leading to obtainment of effects similar to those in the embodiment described above.

The embodiment described above and the modified example thereof may be appropriately combined for use. Processing procedures and processing conditions in this case can be made similar, for example, to the processing procedures and the processing conditions in the embodiment described above and the modified example thereof.

According to an embodiment of the present disclosure, a film formed on a substrate can be improved in property.

What is claimed is:

1. A method of processing a substrate, the method comprising:
(a) performing a cycle including supplying a source containing a predetermined element, carbon, and hydrogen to the substrate and supplying a first modifying agent containing nitrogen to the substrate, a predetermined number of times to form, on the substrate, a first film containing the predetermined element, nitrogen, carbon, and hydrogen bonded to carbon; and
(b) supplying, to the substrate on which the first film is formed, a second modifying agent that is different from the first modifying agent and contains a compound containing a nitrogen-hydrogen bond and a nitrogen-nitrogen bond per molecule or a derivative of the compound, to modify the first film to a second film that is lower in content rate of the hydrogen bonded to carbon than the first film and contains the predetermined element, carbon, and nitrogen.

2. The method according to claim 1, wherein, after (a), (b) is performed without exposing the substrate to an oxygen-containing atmosphere.

3. The method according to claim 1, wherein (b) includes modifying the first film such that a reduction is made in the content rate of the hydrogen bonded to carbon over entirety in a thickness direction of the first film.

4. The method according to claim 1, wherein (b) includes modifying the first film to the second film such that a reduction in content rate of hydrogen in the first film is larger than a reduction in content rate of carbon in the first film.

5. The method according to claim 1, wherein the cycle is performed a plurality of times such that the first film has a desired thickness.

6. The method according to claim 1, wherein (b) includes supplying the second modifying agent in a non-plasma.

7. The method according to claim 1, wherein the first modifying agent contains no nitrogen-nitrogen bond per molecule.

8. The method according to claim 7, wherein the first modifying agent contains a hydronitrogen-based compound.

9. The method according to claim 1, wherein (b) includes causing an intermediate that is produced from the second modifying agent and contains nitrogen with a dangling bond per molecule to react with the hydrogen bonded to carbon in the first film to desorb the hydrogen from the first film.

10. The method according to claim 1, wherein activation energy for an intermediate produced due to decomposition of the second modifying agent to desorb the hydrogen bonded to carbon in the first film is smaller than activation energy for the first modifying agent to desorb the hydrogen bonded to carbon in the first film.

11. The method according to claim 1, wherein the second modifying agent contains at least one compound or derivative selected from the group of diazene, hydrazine, triazene, triazane, monomethylhydrazine, 1,1-dimethylhydrazine, or 1,2-dimethylhydrazine.

12. The method according to claim 1, wherein the source contains a compound containing the predetermined element, carbon, hydrogen, and a halogen element per molecule, and
(b) includes modifying the first film to the second film such that the halogen element in the first film desorbs.

13. The method according to claim 1, wherein (b) includes modifying the first film to the second film such that a reduction is made in content rate of hydrogen bonded to the predetermined element in the first film.

14. The method according to claim 1, wherein the second modifying agent in (b) is smaller in partial pressure than the first modifying agent in (a).

15. The method according to claim 1, wherein the substrate in (b) is lower in temperature than the substrate in (a).

16. The method according to claim 1, further comprising purging a space in which the substrate is located, after (a) but before (b).

17. The method according to claim 1, wherein the predetermined number of times is one, and
a second cycle including (a) and (b) is performed a plurality of times.

18. A method of manufacturing a semiconductor comprising the method according to claim 1.

19. A non-transitory computer-readable recording medium storing a program that causes, by a computer, a substrate processing apparatus to perform:
(a) performing a cycle including supplying a source containing a predetermined element, carbon, and hydrogen to a substrate and supplying a first modifying agent containing nitrogen to the substrate, a predetermined number of times to form, on the substrate, a first film containing the predetermined element, nitrogen, carbon, and hydrogen bonded to carbon; and
(b) supplying, to the substrate on which the first film is formed, a second modifying agent that is different from the first modifying agent and contains a compound containing a nitrogen-hydrogen bond and a nitrogen-nitrogen bond per molecule or a derivative of the compound, to modify the first film to a second film that is lower in content rate of the hydrogen bonded to carbon than the first film and contains the predetermined element, carbon, and nitrogen.

20. A substrate processing apparatus comprising:
a source supplier configured to supply a source containing a predetermined element, carbon, and hydrogen to a substrate;
a first modifying agent supplier configured to supply a first modifying agent containing nitrogen to the substrate;
a second modifying agent supplier configured to supply, to the substrate, a second modifying agent that is different from the first modifying agent and contains a compound containing a nitrogen-hydrogen bond and a nitrogen-nitrogen bond per molecule or a derivative of the compound; and
a controller configured to be capable of controlling the source supplier, the first modifying agent supplier, and the second modifying agent supplier to perform processing including:
(a) performing a cycle including supplying the source to the substrate and supplying the first modifying agent to the substrate, a predetermined number of times to form, on the substrate, a first film containing the predetermined element, nitrogen, carbon, and hydrogen bonded to carbon; and
(b) supplying, to the substrate on which the first film is formed, the second modifying agent to modify the first film to a second film that is lower in content rate of the hydrogen bonded to carbon than the first film and contains the predetermined element, carbon, and nitrogen.
